(19) United States
(12) Patent Application Publication
(10) Pub. No.: US 2025/0280526 A1
(43) Pub. Date: Sep. 4, 2025

(54) SEMICONDUCTOR MEMORY DEVICE

(71) Applicant: Samsung Electronics Co., Ltd., Suwon-si (KR)

(72) Inventors: Jae Won NA, Suwon-si (KR); Chang Sik KIM, Suwon-si (KR); Jong Moo LEE, Suwon-si (KR)

(73) Assignee: Samsung Electronics Co., Ltd., Suwon-si (KR)

(21) Appl. No.: 18/795,562

(22) Filed: Aug. 6, 2024

(30) Foreign Application Priority Data
Feb. 29, 2024 (KR) 10-2024-0029367

(51) Int. Cl. H10B 12/00; H01L 23/00; H01L 25/00; H01L 25/065; H01L 25/18; H10B 80/00

(52) U.S. Cl. CPC H10B 12/315; H01L 24/08; H01L 24/80; H01L 25/0657; H01L 25/18; H01L 25/50; H10B 12/05; H10B 80/00; H01L 2224/08145; H01L 2224/80895; H01L 2224/80896; H01L 2924/1431; H01L 2924/1436

(57) ABSTRACT

The semiconductor device includes a peripheral substrate, a peripheral element on the peripheral substrate, a peripheral wiring structure on the peripheral substrate and connected to the peripheral element, a lower bonding pad on the peripheral wiring structure, a bit line on the lower bonding pad, a bottom surface of the bit line faces the peripheral substrate, a first and second channel pattern on an upper surface of the bit line, a first word line between the first and second channel patterns, a second word line between the first and second channel patterns, a first and second capacitor on the first and second channel patterns respectively, a cell circuit wiring structure on the bottom surface of the bit line and connected to the bit line and an upper bonding pad between the cell circuit wiring structure and the lower bonding pad, the upper bonding pad contacting the lower bonding pad.

### CROSS-REFERENCE TO RELATED APPLICATION

This application claims priority from Korean Patent Application No. 10-2024-0029367 filed on Feb. 29, 2024 in the Korean Intellectual Property Office, and all the benefits accruing therefrom under 35 U.S.C. 119, the contents of which in its entirety are herein incorporated by reference.

### BACKGROUND

The present disclosure relates to semiconductor memory devices, and more specifically, to semiconductor memory devices including a vertical channel transistor (VCT).

In order to meet high performance and low price of a semiconductor memory device as demanded by consumers, it is required to increase integration of the semiconductor memory device. The integration of the semiconductor memory device is an important factor in determining a price thereof. Thus, the semiconductor memory device particularly having increased integration is required.

Integration of a two-dimensional (2D) or planar semiconductor memory device is largely determined based on an occupancy area of a unit memory cell, and therefore is greatly affected by a level of a fine pattern formation skill. However, ultra-expensive equipment is required for formation of fine patterns. Thus, although the integration of the 2D semiconductor memory device is increasing, the increase thereof is limited. Accordingly, a semiconductor memory device including a vertical channel transistor in which a channel extends in a vertical direction is being proposed.

### SUMMARY

A technical purpose to be achieved by the present disclosure is to provide a semiconductor memory device with improved integration and electrical characteristics.

Purposes according to the present disclosure are not limited to the above-mentioned purpose. Other purposes and advantages according to the present disclosure that are not mentioned may be understood based on following descriptions, and may be more clearly understood based on some example embodiments described in the present disclosure. Further, it will be easily understood that the purposes and advantages according to the present disclosure may be realized using means illustrated in the claims and combinations thereof.

According to some aspects of the present disclosure, there is provided a semiconductor memory device comprising a peripheral circuit substrate, a peripheral circuit element on the peripheral circuit substrate, a peripheral circuit wiring structure on the peripheral circuit substrate and connected to the peripheral circuit element, a lower bonding pad on the peripheral circuit wiring structure, a bit line on the lower bonding pad and including an upper surface and a bottom surface opposite to each other in a first direction, wherein the bit line extends in a second direction, and the bottom surface of the bit line faces the peripheral circuit substrate, a first channel pattern on the upper surface of the bit line and including a metal oxide, a second channel pattern on the upper surface of the bit line and including the metal oxide, wherein the first channel pattern is spaced apart from the first channel pattern in the second direction, a first word line between the first channel pattern and the second channel pattern and extending in a third direction, a second word line between the first channel pattern and the second channel pattern and extending in the third direction, wherein the second word line is spaced apart from the first word line in the second direction, a first capacitor and a second capacitor respectively on the first channel pattern and the second channel pattern, and each of the first capacitor and the second capacitor respectively connected to the first channel pattern and the second channel pattern, a cell circuit wiring structure on the bottom surface of the bit line and connected to the bit line and an upper bonding pad between the cell circuit wiring structure and the lower bonding pad, wherein the upper bonding pad is in contact with the lower bonding pad.

According to some aspects of the present disclosure, there is provided a semiconductor memory device comprising a peripheral circuit substrate, a peripheral circuit element on the peripheral circuit substrate, a peripheral circuit wiring structure on the peripheral circuit substrate and connected to the peripheral circuit element, a bit line on the peripheral circuit wiring structure and including an upper surface and a bottom surface opposite to each other in a first direction, wherein the bit line extends in a second direction and the bottom surface of the bit line faces the peripheral circuit substrate, a first channel pattern on the upper surface of the bit line, a second channel pattern on the upper surface of the bit line and spaced apart from the first channel pattern in the second direction, a first word line between the first channel pattern and the second channel pattern and extending in a third direction, a second word line between the first channel pattern and the second channel pattern, extending in the third direction, and spaced apart from the first word line in the second direction, a first capacitor and a second capacitor respectively on the first channel pattern and the second channel pattern, and each of the first capacitor and the second capacitor respectively connected to the first channel pattern and the second channel pattern, an upper bonding pad on the bottom surface of the bit line and connected to the bit line, a first lower bonding pad between the upper bonding pad and the peripheral circuit wiring structure and connected to the peripheral circuit wiring structure, wherein the first lower bonding pad is in contact with the upper bonding pad and a second lower bonding pad spaced apart from the first lower bonding pad in the second direction, and connected to the peripheral circuit wiring structure, wherein the second lower bonding pad is not in contact with the upper bonding pad.

According to some aspects of the present disclosure, there is provided a semiconductor memory device comprising a peripheral circuit substrate, a peripheral circuit element on the peripheral circuit substrate, a peripheral circuit wiring structure on the peripheral circuit substrate and connected to the peripheral circuit element, a first lower bonding pad and a second lower bonding pad on the peripheral circuit wiring structure, a bit line on the first and second lower bonding pads, the bit line including an upper surface and a bottom surface opposite to each other in a first direction, wherein the bit line extends in a second direction, and the bottom surface of the bit line faces the peripheral circuit substrate, a first channel pattern on the upper surface of the bit line and including a metal oxide, a second channel pattern on the upper surface of the bit line and including the metal oxide, wherein the second channel pattern is spaced apart from the first channel pattern in the second direction, a first word line between the first channel pattern and the second channel pattern and extending in a third direction, a second word line between the first channel pattern and the second channel pattern, extending in the third direction, and spaced apart from the first word line in the second direction, a first capacitor and a second capacitor respectively on the first channel pattern and the second channel pattern, and each of the first capacitor and the second capacitor respectively connected to the first channel pattern and the second channel pattern, a cell circuit wiring structure on the bottom surface of the bit line and connected to the bit line, an upper bonding pad between the cell circuit wiring structure and the first lower bonding pad, wherein the upper bonding pad is in contact with the first lower bonding pad, an upper wiring structure connected to the first capacitor and the second capacitor and a contact via spaced apart from the bit line in the second direction and connecting the upper wiring structure and the second lower bonding pad to each other, wherein the upper bonding pad is not in contact with the second lower bonding pad.

It should be noted that the effects of the present disclosure are not limited to those described above, and other effects of the present disclosure will be apparent from the following description.

### BRIEF DESCRIPTION OF DRAWINGS

The above and other aspects and features of the present disclosure will become more apparent by describing in detail some example embodiments thereof with reference to the attached drawings, in which:

FIG. 1 is a schematic perspective view for illustrating a semiconductor memory device according to some example embodiments of the present disclosure.

FIG. 2 is a layout diagram for illustrating a semiconductor memory device according to some example embodiments of the present disclosure.

FIG. 3 is a cross-sectional view cut along A-A in FIG. 1.

FIG. 4 is an enlarged view of a P portion of FIG. 3.

FIGS. 5 to 15 are drawings for illustrating a semiconductor memory device manufacturing method according to some example embodiments of the present disclosure.

FIG. 16 and FIG. 17 are diagrams for illustrating a semiconductor memory device according to some example embodiments of the present disclosure.

FIG. 17 is a cross-sectional view cut along line B-B in FIG. 16.

FIG. 18 is a diagram for illustrating a semiconductor memory device manufacturing method according to some example embodiments of the present disclosure.

### DETAILED DESCRIPTIONS

In this specification, although terms such as “first,” “second,” “upper,” and “lower” are used to describe various elements or components, these elements or components are not limited by these terms. These terms are merely used to distinguish one element or component from another. Therefore, a first element or component mentioned below may be a second element or component within the technical spirit of the present disclosure. Similarly, a lower element or component mentioned below may be an upper element or component within the technical spirit of the present disclosure.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

Some example embodiments of the present disclosure will hereinafter be described in detail with reference to the attached drawings. The same reference numerals are used for the same elements in the drawings, and redundant descriptions thereof will be omitted.

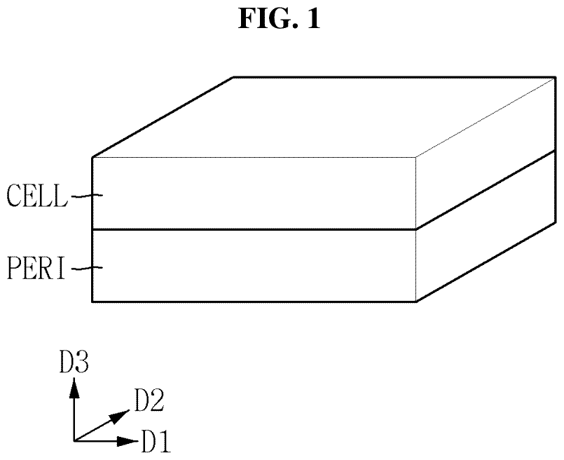

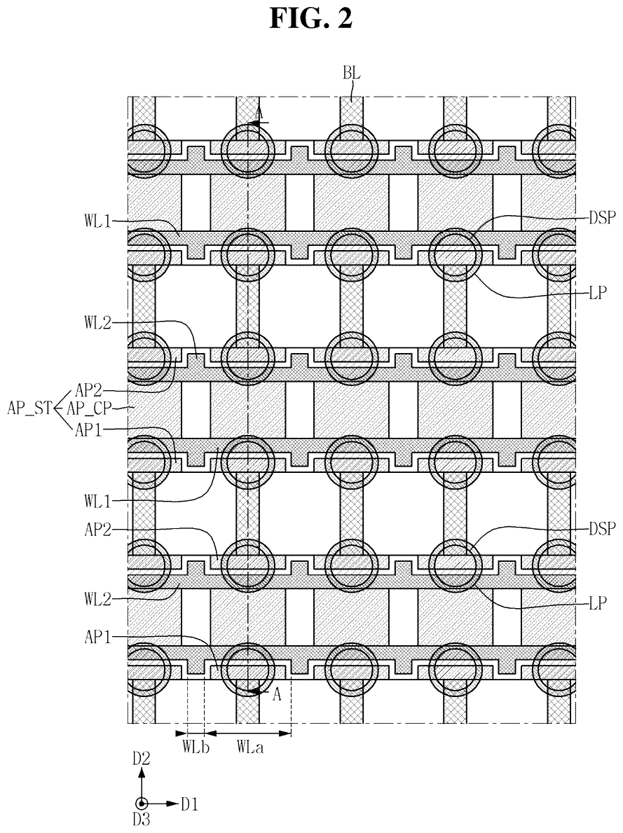

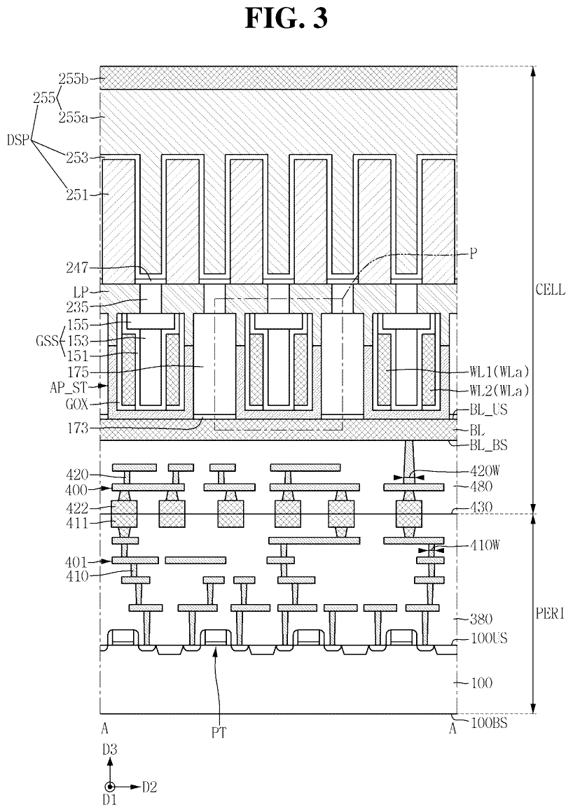

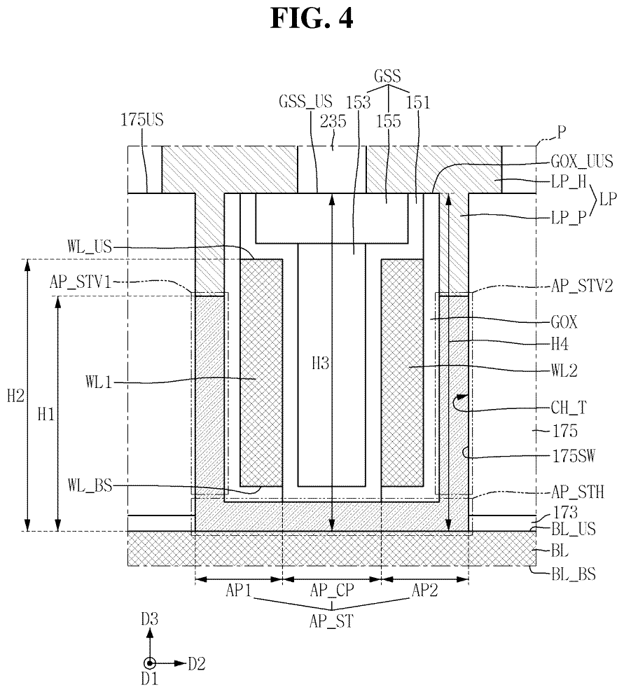

Hereinafter, a semiconductor memory device according to some example embodiments of the present disclosure is described with reference to FIGS. 1 to 4. FIG. 1 is a schematic perspective view for illustrating a semiconductor memory device according to some example embodiments of the present disclosure. FIG. 2 is a layout diagram for illustrating a semiconductor memory device according to some example embodiments of the present disclosure. FIG. 3 is a cross-sectional view cut along A-A in FIG. 1. FIG. 4 is an enlarged view of a P portion of FIG. 3.

A semiconductor memory device according to some example embodiments of the present disclosure may include memory cells, each including a vertical channel transistor (VCT).

Referring to FIGS. 1 to 4, a semiconductor memory device according to some example embodiments of the present disclosure may include a peripheral circuit structure PERI and a cell structure CELL. The peripheral circuit structure PERI and the cell structure CELL may be stacked in a third direction D3. The cell structure CELL may be disposed on top of the peripheral circuit structure PERI. As used herein, a first direction D1, a second direction D2, and the third direction D3 may intersect each other. The first direction D1, the second direction D2, and the third direction D3 may be perpendicular or substantially perpendicular to each other.

The semiconductor memory device according to some example embodiments may have a C2C (chip to chip) structure. In the C2C structure, an upper chip including the cell structure CELL is manufactured on a first wafer, and a lower chip (e.g., the peripheral circuit structure PERI) is manufactured on a second wafer that is different from the first wafer, and the upper chip and the lower chip are bonded to each other in a bonding scheme.

In one example, the bonding scheme may refer to a scheme that electrically connects an upper bonding pad (422 in FIG. 3) formed in the upper chip to a lower bonding pad (411 in FIG. 3) formed in the lower chip. For example, when each of the upper bonding pad 422 and the lower bonding pad 411 is made of copper (Cu), the bonding scheme may be a Cu—Cu bonding scheme. However, this is only an example, and each of the upper bonding pad 422 and lower bonding pad 411 may be made of various other metals such as aluminum (Al) or tungsten (W).

The peripheral circuit structure PERI may include a peripheral circuit substrate 100, a peripheral circuit element PT, a peripheral circuit wiring structure 401, and the lower bonding pad 411.

The peripheral circuit substrate 100 may include, for example, a semiconductor substrate such as a silicon substrate, a germanium substrate, or a silicon-germanium substrate. Alternatively, the peripheral circuit substrate 100 may include a silicon-on-insulator (SOI) substrate or a germanium-on-insulator (GOI) substrate.

The peripheral circuit substrate 100 may extend in the first direction D1 and the second direction D2. The peripheral circuit substrate 100 may include an upper surface 100US and a lower surface 100BS that are opposite to each other.

The peripheral circuit element PT may be formed on the upper surface 100US of the peripheral circuit substrate 100. The peripheral circuit element PT may constitute a peripheral circuit that controls an operation of the semiconductor memory device. For example, the peripheral circuit element PT may include a control logic, a row decoder, and a page buffer.

The peripheral circuit element PT may include, for example, a transistor. However, the example embodiments of the present disclosure are not limited thereto. For example, the peripheral circuit element PT may include various active elements such as transistors, as well as various passive elements such as capacitors, resistors, and inductors.

The peripheral circuit wiring structure 401 may be disposed on the upper surface 100US of the peripheral circuit substrate 100. Alternatively, the peripheral circuit wiring structure 401 may be disposed on the peripheral circuit element PT. For example, a peripheral interlayer insulating film 380 may be formed on the upper surface 100US of the peripheral circuit substrate 100. The peripheral circuit wiring structure 401 may be formed within the peripheral interlayer insulating film 380 and may be electrically connected to the peripheral circuit element PT.

The peripheral interlayer insulating film 380 may include, but is not limited to, at least one of, for example, silicon oxide, silicon oxynitride, and a low-k material with a lower dielectric constant than that of silicon oxide.

The peripheral circuit wiring structure 401 may include a plurality of first vias 410. A width 410W of the first via 410 may increase as it extends away from the upper surface 100US of the peripheral circuit substrate 100 in the third direction D3. In other words, the width 410W of the first via 410 may become smaller as it extends away from the lower bonding pad 411, which will be described later, in the third direction D3. The width 410W of the first via 410 may become smaller as it extends away from a boundary 430 of the peripheral circuit structure PERI and the cell structure CELL.

The lower bonding pad 411 may be disposed on the peripheral circuit wiring structure 401 and within the peripheral interlayer insulating film 380. The lower bonding pad 411 may be exposed from the peripheral interlayer insulating film 380.

The lower bonding pad 411 may be connected to the upper bonding pad 422, which will be described later. The lower bonding pad 411 may be connected to the upper bonding pad 422 at the boundary 430 between the peripheral circuit structure PERI and the cell structure CELL. Thus, the peripheral circuit element PT, a bit line BL, a channel structure AP_ST, a data storage pattern DSP, etc. may be electrically connected to each other.

The cell structure CELL may include bit lines BL, a protruding insulating pattern 175, the channel structures AP_ST, word lines WL1 and WL2, a gate insulating film GOX, a gate isolation pattern GSS, a landing pad LP, the data storage patterns DSP, a cell circuit wiring structure 400, and the upper bonding pad 422.

The bit lines BL may be disposed on the peripheral circuit structure PERI. More specifically, the bit lines BL may be disposed on the lower bonding pad 411.

Each of the bit lines BL may include an upper surface BL_US and a bottom surface BL_BS that are opposite to each other in the third direction D3. The bottom surface BL_BS of the bit line BL may face the upper surface 100US of the peripheral circuit substrate 100. The bit lines BL may extend in an elongated manner in the second direction D2. Adjacent bit lines BL may be spaced apart from each other in the first direction D1. Although not shown, a lower insulating film made of an insulating material may be disposed between the bit lines BL spaced apart from each other in the first direction D1.

The bit line BL may include, at least one of, for example, doped semiconductor material, conductive metal nitride, conductive metal silicon nitride, metal carbonitride, conductive metal silicide, conductive metal oxide, two-dimensional material, metal, and metal alloy. Although each bit line BL is shown as being embodied as a single film, example embodiments of the present disclosure are not limited thereto.

The protruding insulating pattern 175 may be disposed on the bit line BL and the lower insulating film. A cell lower etch stop film 173 may be disposed between the protruding insulating pattern 175 and the bit line BL. Additionally, the cell lower etch stop film 173 may be disposed between the protruding insulating pattern 175 and the lower insulating film. Each of the protruding insulating pattern 175 and the cell lower etch stop film 173 may be made of an insulating material. The cell lower etch stop film 173 may include a material having an etch selectivity with respect to a material of the protruding insulating pattern 175. For example, the protruding insulating pattern 175 may be made of an oxide-based insulating material. However, the example embodiments of the present disclosure are not limited thereto. Unlike what is shown, the cell lower etch stop film 173 may not be disposed between the protruding insulating pattern 175 and the lower insulating film.

The protruding insulating pattern 175 may have a plurality of channel trenches CH_T defined therein. Each channel trench CH_T may extend in an elongated manner in the first direction D1. Adjacent channel trenches CH_T may be spaced apart from each other in the second direction D2.

A bottom surface of each channel trench CH_T may be defined by the bit line BL and the lower insulating film. A sidewall of each channel trench CH_T may be defined by the protruding insulating pattern 175 and the cell lower etch stop film 173. At least a portion of the sidewall of the channel trench CH_T may be a sidewall 175SW of the protruding insulating pattern 175. When the cell lower etch stop film 173 is not disposed, the sidewall of each channel trench CH_T may be defined by the protruding insulating pattern 175.

The channel structure AP_ST may be disposed on each bit line BL. A plurality of channel structures AP_ST may be connected to one bit line BL. The plurality of channel structures AP_ST disposed on one bit line BL may be spaced apart from each other in the second direction D2.

The channel structure AP_ST may be disposed in the channel trench CH_T extending in the first direction D1. The plurality of channel structures AP_ST may be disposed within one channel trench CH_T. The plurality of channel structures AP_ST disposed in the channel trench CH_T may be spaced apart from each other in the first direction D1.

For example, the channel structures AP_ST may be two-dimensionally arranged along the first direction D1 and the second direction D2 that intersect each other.

The channel structure AP_ST may extend along a sidewall and a bottom surface of the channel trench CH_T. In a cross section cut in the second direction D2, the channel structure AP_ST may have a “U” shape.

The channel structure AP_ST may include a horizontal portion AP_STH, a first vertical portion AP_STV1, and a second vertical portion AP_STV2. The first vertical portion AP_STV1 of the channel structure AP_ST and the second vertical portion AP_STV2 of the channel structure AP_ST may protrude in the third direction D3 from the horizontal portion AP_STH of the channel structure AP_ST.

The horizontal portion AP_STH of the channel structure AP_ST may extend along the bottom surface of the channel trench CH_T. In a cross section cut in the second direction D2, the horizontal portion AP_STH of the channel structure AP_ST may extend along the upper surface BL_US of the bit line BL. The horizontal portion AP_STH of the channel structure AP_ST is connected to the bit line BL. For example, the horizontal portion AP_STH of the channel structure AP_ST may contact the upper surface BL_US of the bit line BL.

The first vertical portion AP_STV1 of the channel structure AP_ST and the second vertical portion AP_STV2 of the channel structure AP_ST may extend along the sidewall of the channel trench CH_T. In the cross section cut in the second direction D2, each of the first vertical portion AP_STV1 of the channel structure AP_ST and the second vertical portion AP_STV2 of the channel structure AP_ST may extend along the protruding insulating pattern 175.

The channel structure AP_ST may include an oxide semiconductor material.

For example, the channel structure AP_ST may include metal oxide. The metal oxide may include, for example, one of indium gallium zinc oxide (IGZO), indium zinc oxide (IZO) doped with impurities, indium oxide (InO), zinc oxide (ZnO), gallium oxide (GaO), and tin oxide (SnO), aluminum zinc oxide (AZO), and indium tin oxide (ITO). In indium zinc oxide (IZO) doped with the impurities, the doped impurity may include at least one of, for example, magnesium (Mg), strontium (Sr), barium (Ba), scandium (Sc), yttrium (Y), lanthanum (La), titanium (Ti), zirconium (Zr), hafnium (Hf), aluminum (Al), tin (Sn), and tantalum (Ta).

In some example embodiments, the channel structure AP_ST may include amorphous metal oxide. The amorphous metal oxides may include one of, for example, indium gallium zinc oxide (IGZO), impurity-doped indium zinc oxide (IZO), indium oxide (InO), zinc oxide (ZnO), gallium oxide (GaO), and tin oxide (SnO), aluminum zinc oxide (AZO), and indium tin oxide (ITO). Additionally, in some example embodiments, the channel structure AP_ST may include a c-axis aligned crystalline (CAAC) IGZO.

In the semiconductor memory device according to some example embodiments, the channel structure AP_ST may be in a surface treated state. The surface treatment may be performed using plasma of at least one of nitrogen (N₂), hydrogen (H₂), oxygen (O₂), fluorine (F) or argon (Ar). When the horizontal portion AP_STH of the channel structure AP_ST is surface-treated using the plasma, an electron concentration of the channel structure AP_ST may increase. Therefore, a contact resistance between the channel structure AP_ST and the bit line BL may be lowered. In this case, the electrical characteristics of the semiconductor memory device may be improved.

In the semiconductor memory device according to some example embodiments, the channel structure AP_ST may be doped with impurities. The impurities in the channel structure AP_ST may include at least one of phosphorus (P), arsenic (As), antimony (Sb), bismuth (Bi), and/or boron (B). However, the example embodiments of the present disclosure are not limited thereto. When the channel structure AP_ST is doped with the impurities, the electron concentration thereof increases, so that the contact resistance between the channel structure AP_ST and the bit line BL may be lowered. In this case, the electrical characteristics of the semiconductor memory device may be improved.

The channel structure AP_ST may include a first channel pattern AP1, a second channel pattern AP2, and a connection channel pattern AP_CP. The connection channel pattern AP_CP connects the first channel pattern AP1 and the second channel pattern AP2 to each other. The first channel pattern AP1 and the second channel pattern AP2 may be spaced apart from each other in the second direction D2.

The first channel pattern AP1, the second channel pattern AP2, and the connection channel pattern AP_CP may be disposed on the bit line BL. The first channel pattern AP1, the second channel pattern AP2, and the connection channel pattern AP_CP are connected to the bit line BL. The first channel pattern AP1, the second channel pattern AP2, and the connection channel pattern AP_CP may contact the upper surface BL_US of the bit line BL.

The first channel pattern AP1 may include a portion of the horizontal portion AP_STH of the channel structure AP_ST and the first vertical portion AP_STV1 of the channel structure AP_ST. The portion of the horizontal portion AP_STH of the channel structure AP_ST may be a horizontal portion of the first channel pattern AP1. The first vertical portion AP_STV1 of the channel structure AP_ST may be a vertical portion of the first channel pattern AP1.

The second channel pattern AP2 may include another portion of the horizontal portion AP_STH of the channel structure AP_ST and the second vertical portion AP_STV2 of the channel structure AP_ST. The another portion of the horizontal portion AP_STH of the channel structure AP_ST may be a horizontal portion of the second channel pattern AP2. The second vertical portion AP_STV2 of the channel structure AP_ST may be a vertical portion of the second channel pattern AP2.

The connection channel pattern AP_CP includes the remainder of the horizontal portion AP_STH of the channel structure AP_ST. In other words, the connection channel pattern AP_CP includes the remainder of the horizontal portion AP_STH of the channel structure AP_ST other than the horizontal portion included in the first channel pattern AP1 and the horizontal portion included in the second channel pattern AP2.

Based on the first word line WL1 and the second word line WL2, which will be described later, the first channel pattern AP1, the second channel pattern AP2, and the connection channel pattern AP_CP may be distinguished from each other. For example, the first word line WL1 may include an inner sidewall facing the sidewall 175SW of the protruding insulating pattern 175, and an outer sidewall that is opposite to the inner sidewall in the second direction D2. A boundary between the first channel pattern AP1 and the connection channel pattern AP_CP may coincide with an extension line of the outer sidewall of the first word line WL1 extending in the third direction D3. In another example, the second word line WL2 may include an inner sidewall facing the sidewall 175SW of the protruding insulating pattern 175, and an outer sidewall that is opposite to the inner sidewall in the second direction D2. A boundary between the second channel pattern AP2 and the connection channel pattern AP_CP may coincide with an extension line of the outer sidewall of the second word line WL2 extending in the third direction D3.

In the semiconductor memory device according to some example embodiments, each of the first channel pattern AP1, the second channel pattern AP2, and the connection channel pattern AP_CP may include metal oxide.

The first word line WL1 and the second word line WL2 may be disposed on the channel structure AP_ST. The first word line WL1 and the second word line WL2 may be disposed in the channel trench CH_T.

Each of the first word line WL1 and the second word line WL2 may extend in the first direction D1. The first word lines WL1 and the second word lines WL2 may be alternately arranged with each other in the second direction D2. The first word line WL1 is spaced apart from the second word line WL2 in the second direction D2.

The first word line WL1 and the second word line WL2 may be spaced apart from the bit line BL in the third direction D3. The first word line WL1 and the second word line WL2 may intersect the bit line BL.

The first word line WL1 and the second word line WL2 may be disposed on the horizontal portion AP_STH of the channel structure AP_ST. The first word line WL1 and the second word line WL2 may be disposed between the first vertical portion AP_STV1 of the channel structure AP_ST and the second vertical portion AP_STV2 of the channel structure AP_ST.

The first word line WL1 may be disposed on the first channel pattern AP1. The second word line WL2 may be disposed on the second channel pattern AP2. The first word line WL1 and the second word line WL2 may be disposed between the first channel pattern AP1 and the second channel pattern AP2. The first channel pattern AP1 may be disposed closer to the first word line WL1 than to the second word line WL2. The second channel pattern AP2 may be disposed closer to the second word line WL2 than to the first word line WL1.

Each of the first word line WL1 and the second word line WL2 may have a width in the second direction D2 (see FIG. 2). A width of a portion the first word line WL1 that overlaps the channel structure AP_ST in the third direction D3 may be different from a width of a portion the first word line WL1 that does not overlap the channel structure AP_ST. A width of a portion of the second word line WL2 that overlaps the channel structure AP_ST in the third direction D3 may be different from a width of a portion of the second word line WL2 that does not overlap the channel structure AP_ST.

For example, as shown in FIG. 2, each of the first word line WL1 and the second word line WL2 may include a first portion WLa of the word line and a second portion WLb of the word line. A width in the second direction D2 of the first portion WLa of the word line may be smaller than a width in the second direction of the second portion WLb of the word line. For example, the first portion WLa of the word line may be disposed on the channel structure AP_ST. The first portion WLa of the word line may be disposed on the first channel pattern AP1 and the second channel pattern AP2.

Each of the first word line WL1 and the second word line WL2 may include first portions WLa of the word line and second portions WLb of the word line alternately arranged with each other along the first direction D1. Each channel structure AP_ST may be disposed between the second portions WLb of the word line adjacent to each other in the first direction D1. Each of the first active patterns AP1 may be disposed between the second portions WLb of the first word line WL1 adjacent to each other in the first direction D1. Each of the second active patterns AP2 may be disposed between the second portions WLb of the second word line WL2 adjacent to each other in the first direction D1.

The channel structure AP_ST is not disposed under the second portion WLb of the word line.

Each of the first and second word lines WL1 and WL2 may include a conductive material. For example, each of the first and second word lines WL1 and WL2 may include at least one of doped polysilicon, conductive metal nitride, conductive metal silicon nitride, metal carbonitride, conductive metal silicide, conductive metal oxide, two-dimensional material, metal, and metal alloy.

Each of the first and second word lines WL1 and WL2 may include an upper surface WL_US and a lower surface WL_BS that are opposite to each other in the third direction D3. The lower surface WL_BS of each of the first and second word lines WL1 and WL2 may face the bit line BL.

Based on the upper surface BL_US of the bit line BL, a vertical level of the upper surface WL_US of each of the first and second word lines WL1 and WL2 may be higher than a vertical level of a top level of each of the vertical portions AP_STV1 and AP_STV2 of the channel structure AP_ST. A top level of each of the channel patterns AP1 and AP2 may be the top level of each of the vertical portions AP_STV1 and AP_STV2 of the channel structure. A height H1 from the upper surface BL_US of the bit line BL to the top level of each of the vertical portions AP_STV1 and AP_STV2 of the channel structure AP_ST may be smaller than a height H2 from the upper surface BL_US of the bit line BL to the upper surface WL_US of each of the first and second word lines WL1 and WL2.

The gate insulating film GOX may be disposed between the first word line WL1 and the channel structure AP_ST and between the second word line WL2 and the channel structure AP_ST. The gate insulating film GOX may be disposed between the first word line WL1 and the first active pattern AP1 and between the second word line WL2 and the second active pattern AP2. The gate insulating film GOX may extend in the first direction D1 in a parallel manner to the first word line WL1 and the second word line WL2.

The gate insulating film GOX may extend along the first vertical portion AP_STV1 of the channel structure AP_ST. The gate insulating film GOX may extend along the second vertical portion AP_STV2 of the channel structure AP_ST. In the semiconductor memory device according to some example embodiments, the gate insulating film GOX may not be disposed on a portion of the horizontal portion AP_STH of the channel structure AP_ST that does not overlap the first word line WL1 and the second word line WL2 in the third direction D3. In a cross-sectional view, the gate insulating film GOX between the first word line WL1 and the channel structure AP_ST may be isolated from the gate insulating film GOX between the second word line WL2 and the channel structure AP_ST.

The gate insulating film GOX may include a silicon oxide film, a silicon oxynitride film, a high dielectric constant insulating film with a higher dielectric constant than that of the silicon oxide film, or a combination thereof.

A portion of the gate insulating film GOX may protrude in the third direction D3 beyond the upper surface WL_US of each of the first and second word lines WL1 and WL2. A portion of the gate insulating film GOX may protrude in the third direction D3 beyond the top level of each of the vertical portions AP_STV1 and AP_STV2 of the channel structure AP_ST.

A height H4 from the upper surface BL_US of the bit line BL to a top level GOX_UUS of the gate insulating film GOX may be larger than the height H1 from the upper surface BL_US of the bit line BL to the top level of each of the vertical portions AP_STV1 and AP_STV2 of the channel structure AP_ST. The height H4 from the upper surface BL_US of the bit line BL to the top level GOX_UUS of the gate insulating film GOX may be larger than the height H2 from the upper surface BL_US of the bit line BL to the upper surface WL_US of each of first and second word lines WL1 and WL2.

The gate isolation pattern GSS may be disposed on the bit line BL and the lower insulating film. The gate isolation pattern GSS may be disposed within the channel trench CH_T. The gate isolation pattern GSS may be disposed on the channel structure AP_ST, the first word line WL1, and the second word line WL2.

In the semiconductor memory device according to some example embodiments, the gate isolation pattern GSS may contact the channel structure AP_ST. The gate isolation pattern GSS may be disposed on the connection channel pattern AP_CP. The gate isolation pattern GSS may contact the horizontal portion AP_STH of the channel structure AP_ST. The gate isolation pattern GSS may be spaced apart from the bit line BL in the third direction D3.

The gate isolation pattern GSS may be disposed between the first word line WL1 and the second word line WL2 adjacent to each other in the second direction D2. The first word line WL1 and the second word line WL2 may be isolated from each other via the gate isolation pattern GSS. The gate isolation pattern GSS may extend in the first direction D1 and between the first word line WL1 and the second word line WL2.

The first word line WL1 may be disposed between the gate isolation pattern GSS and the channel structure AP_ST. The second word line WL2 may be disposed between the gate isolation pattern GSS and the channel structure AP_ST. The first word line WL1 may be disposed between the gate isolation pattern GSS and the first channel pattern AP1. The second word line WL2 may be disposed between the gate isolation pattern GSS and the second channel pattern AP2.

The gate isolation pattern GSS may include a horizontal portion and a protrusion. The protrusion of the gate isolation pattern GSS may protrude in the third direction D3 from the horizontal portion of the gate isolation pattern GSS toward the bit line BL. The protrusion of the gate isolation pattern GSS may be closer to the bit line BL than the horizontal portion of the gate isolation pattern GSS may be. The horizontal portion of the gate isolation pattern GSS may be disposed on the upper surface WL_US of each of the first and second word lines WL1 and WL2. In a cross-sectional view, the gate isolation pattern GSS may have a “T” shape.

The gate isolation pattern GSS may include a gate isolation liner 151, a gate isolation filling film 153, and a gate isolation capping film 155. The gate isolation liner 151 may extend along the upper surface WL_US of each of the first and second word lines WL1 and WL2 and the outer sidewall of each of the first and second word lines WL1 and WL2. The gate isolation liner 151 may extend along the horizontal portion AP_STH of the channel structure AP_ST. The gate isolation liner 151 may contact the connection channel pattern AP_CP. The gate isolation liner 151 may extend along a portion of the gate insulating film GOX protruding upwardly beyond the upper surface WL_US of each of the first and second word lines WL1 and WL2. Unlike what is shown, the gate isolation liner 151 may not extend along the portion of the gate insulating film GOX protruding beyond the upper surface WL_US of each of the first and second word lines WL1 and WL2.

The gate isolation filling film 153 may be disposed on the gate isolation liner 151. The gate isolation capping film 155 may be disposed on the gate isolation filling film 153. Each of the gate isolation liner 151, the gate isolation filling film 153, and the gate isolation capping film 155 may be made of an insulating material. Unlike what is shown, in some example embodiments, the gate isolation pattern GSS may be embodied as a single film. Unlike what is shown, in some example embodiments, the gate isolation filling film 153 and the gate isolation capping film 155 may be integrated into a single film. That is, the gate isolation filling film 153 and the gate isolation capping film 155 may have an integrated structure.

Based on the upper surface BL_US of the bit line BL, the upper surface GSS_US of the gate isolation pattern GSS may be disposed at the same vertical level as that of the upper surface 175US of the protruding insulating pattern 175. However, the present disclosure is not limited to thereto.

A height H3 from the upper surface BL_US of the bit line BL to the upper surface GSS_US of the gate isolation pattern GSS may be larger than the height H1 from the upper surface BL_US of the bit line BL to the top level of each of the vertical portions AP_STV1 and AP_STV2 of the channel structure AP_ST. The height H3 from the upper surface BL_US of the bit line BL to the upper surface GSS_US of the gate isolation pattern GSS may be larger than the height H2 from the upper surface BL_US of the bit line BL to the upper surface WL_US of each of the first and second word lines WL1 and WL2.

Although it is shown that the height H3 from the upper surface BL_US of the bit line BL to the upper surface GSS_US of the gate isolation pattern GSS is equal to the height H4 from the upper surface BL_US of the bit line BL to the top level GOX_UUS of the gate insulating film GOX, the present disclosure is not limited thereto.

The landing pads LP may be disposed on the channel structure AP_ST. The landing pads LP may be connected to the first vertical portion AP_STV1 of the channel structure AP_ST and the second vertical portion AP_STV2 of the channel structure AP_ST.

The landing pads LP may be disposed on the first channel pattern AP1 and the second channel pattern AP2. The landing pads LP may be connected to the first channel pattern AP1 and the second channel pattern AP2.

In a plan view, each of the landing pads LP may have various shapes such as circular, oval, rectangular, square, diamond, and hexagonal shapes.

Each of the landing pads LP may include a horizontal portion LP_H and a protrusion LP_P. The horizontal portion LP_H of the landing pad LP may be disposed on the upper surface 175US of the protruding insulating pattern 175 and the upper surface GSS_US of the gate isolation pattern GSS. The protrusion LP_P of the landing pad LP may protrude in the third direction D3 from the horizontal portion LP_H of the landing pad LP toward the bit line BL.

Based on the upper surface BL_US of the bit line BL, a vertical level of a bottom surface of the landing pad LP may be lower than a vertical level of the upper surface GSS_US of the gate isolation pattern GSS. In other words, the protrusion LP_P of the landing pad LP may be disposed between the protruding insulating pattern 175 and the gate isolation pattern GSS. A height from the upper surface BL_US of the bit line BL to the bottom surface of the landing pad LP may be smaller than the height H4 from the upper surface BL_US of the bit line BL to the top level GOX_UUS of the gate insulating film.

The pad isolation insulating patterns 235 may be disposed between the landing pads LP. In a plan view, the landing pads LP may be arranged in a matrix form along the first direction D1 and the second direction D2. The upper surface of the landing pads LP may be coplanar with the upper surface of the pad isolation insulating pattern 235. However, example embodiments of the present disclosure are not limited thereto.

Each of the landing pads LP may include a conductive material. The landing pad LP may include, for example, at least one of doped polysilicon, conductive metal nitride, conductive metal silicon nitride, metal carbonitride, conductive metal silicide, conductive metal oxide, two-dimensional material, metal, and/or metal alloy.

The data storage patterns DSP may be respectively disposed on the landing pads LP. The data storage patterns DSP may be connected to the first vertical portion AP_STV1 of the channel structure AP_ST and the second vertical portion AP_STV2 of the channel structure AP_ST. The data storage patterns DSP may be connected to the first and second channel patterns AP1 and AP2, respectively. The data storage patterns DSP may be respectively connected to the first and second channel patterns AP1 and AP2 via the landing pads LP.

The data storage patterns DSP may be arranged in a matrix form along the first direction D1 and the second direction D2, as shown in FIG. 2. The data storage pattern DSP may entirely overlap or partially overlap the landing pad LP in the third direction D3. The data storage pattern DSP may contact an entirety or a portion of an upper surface of the landing pad LP.

For example, the data storage pattern DSP may act as a capacitor. The first channel pattern AP1 may be connected to a first capacitor. The second channel pattern AP2 may be connected to a second capacitor.

The data storage pattern DSP may include a storage electrode 251, a plate electrode 255a, and a capacitor dielectric layer 253 interposed between the storage electrode 251 and the plate electrode 255. The storage electrode 251 may contact the landing pad LP. In a plan view, the storage electrode 251 may have various shapes, such as circular, oval, rectangular, square, diamond, or hexagonal shapes. The storage electrodes 251 may extend through an upper etch stop film 247. The upper etch stop film 247 may be disposed on the pad isolation insulating pattern 235. The upper etch stop film 247 may be made of an insulating material.

The plate electrode 255 may include a lower plate electrode 255a and an upper plate electrode 255b. Unlike what is shown, the plate electrode 255 may be embodied as a single film. Each of the storage electrode 251 and the plate electrode 255 may include at least one of, for example, a conductive semiconductor material, a conductive metal nitride, a conductive metal silicon nitride, a metal carbonitride, a conductive metal silicide, a conductive metal oxide, and/or a metal. The capacitor dielectric layer 253 may include at least one of a ferroelectric material, an antiferroelectric material, and/or a paraelectric material. For example, the capacitor dielectric layer 253 may include one of a ferroelectric material, an antiferroelectric material, a paraelectric material, a combination of a ferroelectric material and an antiferroelectric material, a combination of a ferroelectric material and a paraelectric material, a combination of a paraelectric material and an antiferroelectric material, and a combination of a ferroelectric material, an antiferroelectric material, and/or a paraelectric material.

Alternatively, each of the data storage patterns DSP may be embodied as a variable resistance pattern that may be switched to between two resistance states under an electrical pulse applied to a memory element. For example, each of the data storage patterns DSP may include a phase-change material having a crystal state varying depending on an amount of current, perovskite compounds, transition metal oxides, magnetic materials, ferromagnetic materials, or antiferromagnetic materials.

The cell circuit wiring structure 400 may be disposed on the bottom surface BL_BS of the bit line BL. The cell circuit wiring structure 400 may be connected to the bit line BL. For example, a first cell interlayer insulating film 480 may be formed on the bottom surface BL_BS of the bit line BL. The cell circuit wiring structure 400 may be formed within the first cell interlayer insulating film 480 and electrically connected to the bit line BL.

The first cell interlayer insulating film 480 may include, but is not limited to, at least one of silicon oxide, silicon oxynitride, and a low-k material with a dielectric constant smaller than that of silicon oxide.

The cell circuit wiring structure 400 may include a plurality of second vias 420. A width 420W of the second via 420 may increase as it extends away from the bottom surface BL_BS of the bit line BL in the third direction D3. In other words, the width 420W of the second via 420 may become smaller as it extends away from the upper bonding pad 422, which will be described later, in the third direction D3. The width 420W of the second via 420 may become smaller as it extends away from the boundary 430 between the peripheral circuit structure PERI and the cell structure CELL.

The upper bonding pad 422 may be disposed on the cell circuit wiring structure 400 and within the first cell interlayer insulating film 480. The upper bonding pad 422 may be exposed from the first cell interlayer insulating film 480.

The upper bonding pad 422 may be connected to the lower bonding pad 411. The upper bonding pad 422 may be connected to the lower bonding pad 411 at the boundary 430 between the cell structure CELL and the peripheral circuit structure PERI.

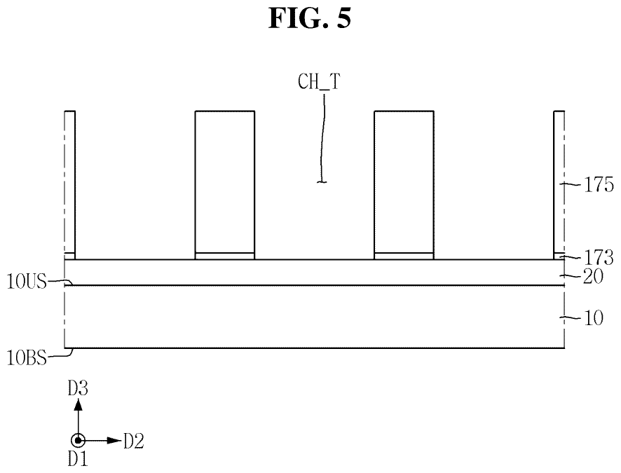

FIGS. 5 to 15 are drawings for illustrating a semiconductor memory device manufacturing method according to some example embodiments of the present disclosure. For convenience of description, contents duplicate with what has been described above in FIGS. 1 to 4 are briefly described or the descriptions thereof are omitted.

Referring to FIG. 5, an auxiliary substrate 10 and a first etch stop film 20 disposed on the auxiliary substrate 10 may be provided. The protruding insulating pattern 175 may be formed on the first etch stop film 20. The cell lower etch stop film 173 may be formed between the protruding insulating pattern 175 and the first etch stop film 20. However, example embodiments of the present disclosure are not limited thereto.

The auxiliary substrate 10 may include an upper surface 10US and a lower surface 10BS opposite to the upper surface 10US. The auxiliary substrate 10 may extend in the first direction D1 and the second direction D2. The auxiliary substrate 10 may be a silicon substrate, or may include a material other than silicon, such as silicon germanium, indium antimonide, lead telluride compound, indium arsenide, indium phosphide, gallium arsenide or gallium antimonide. However, example embodiments of the present disclosure are not limited thereto.

The first etch stop film 20 may be formed on the upper surface 10US of the auxiliary substrate 10. The first etch stop film 20 may include an insulating material. For example, the first etch stop film 20 may include silicon nitride, silicon oxynitride, silicon carbon nitride, aluminum oxide, etc. However, example embodiments of the present disclosure are not limited thereto.

The protruding insulating pattern 175 may include a plurality of channel trenches CH_T extending in the first direction D1. The channel trench CH_T may expose the first etch stop film 20.

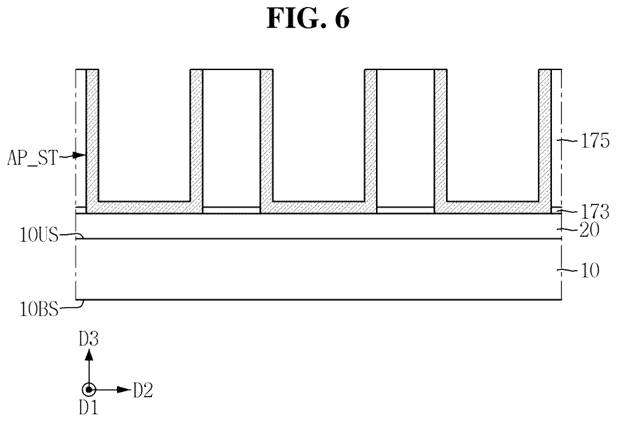

Next, referring to FIG. 6, the channel structure AP_ST extending along the sidewall and the bottom surface of each of the plurality of channel trenches CH_T may be formed. The channel structure AP_ST may be formed within the channel trench CH_T.

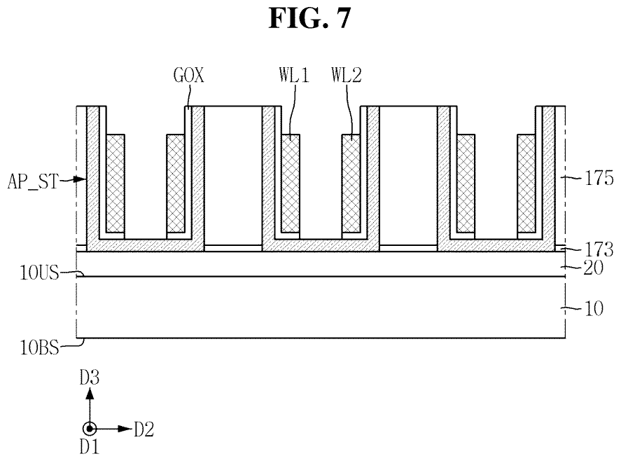

Next, referring to FIG. 7, the gate insulating film GOX and the first and second word lines WL2 may be formed within the channel trench CH_T.

The gate insulating film GOX may be formed along a profile of the channel structure AP_ST. The gate insulating film GOX may be formed using at least one of physical vapor deposition (PVD), thermal chemical vapor deposition (thermal CVD), low pressure chemical vapor deposition (LP-CVD), plasma enhanced chemical vapor deposition (PE-CVD), or atomic layer deposition (ALD). However, example embodiments of the present disclosure are not limited thereto.

The gate insulating film GOX may be formed, and then, the first word line WL1 and the second word line WL2 may be formed on the gate insulating film GOX. The first word line WL1 and the second word line WL2 may be formed on the gate insulating film GOX and in the channel trench CH_T.

Forming the first word line WL1 and the second word line WL2 may include depositing a gate conductive film on the gate insulating film GOX and then performing an anisotropic etching process on the gate conductive film.

During the anisotropic etching process on the gate conductive film, a portion of the gate insulating film GOX may be etched. Thus, a portion of the gate insulating film GOX between the first word line WL1 and the channel structure AP_ST may be isolated from a portion of the gate insulating film GOX between the second word line WL2 and the channel structure AP_ST. Unlike what is shown, during the anisotropic etching process on the gate conductive film, the gate insulating film GOX may be used as an etch stop film.

The upper surface of the first word line WL1 and the upper surface of the second word line WL2 may be located at a lower level than that of the upper surface of the protruding insulating pattern 175.

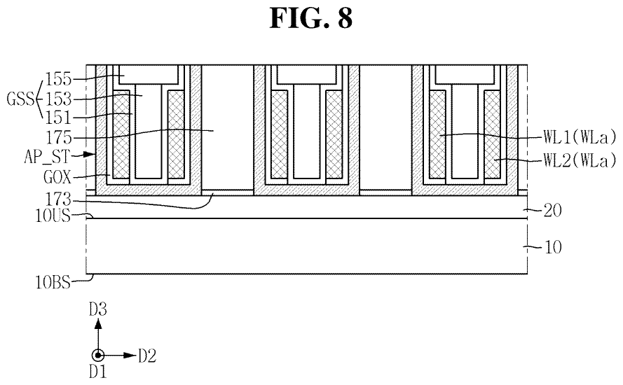

Next, referring to FIG. 8, the gate isolation pattern GSS may be formed.

The gate isolation pattern GSS may be formed on the first word line WL1 and the second word line WL2. The gate isolation pattern GSS may fill the channel trench CH_T.

More specifically, the gate isolation liner 151 may be formed along a profile of the first word line WL1 and a profile of the second word line WL2. The gate isolation liner 151 may be formed on the upper surface of the protruding insulating pattern 175.

A pre-filling film may be formed on the gate isolation liner 151. The pre-filling film may be formed on the upper surface of the protruding insulating pattern 175. A portion of the pre-filling film may be removed, such that the gate isolation filling film 153 may be formed on the gate isolation liner 151.

A pre-capping film may be formed on the gate isolation filling film 153. The pre-capping film may be formed on the upper surface of the protruding insulating pattern 175. A portion of the pre-capping film may be removed such that the gate isolation capping film 155 may be formed. While the gate isolation capping film 155 is being formed, the gate isolation liner 151 and the pre-capping film formed on the upper surface of the protruding insulating pattern 175 may be removed.

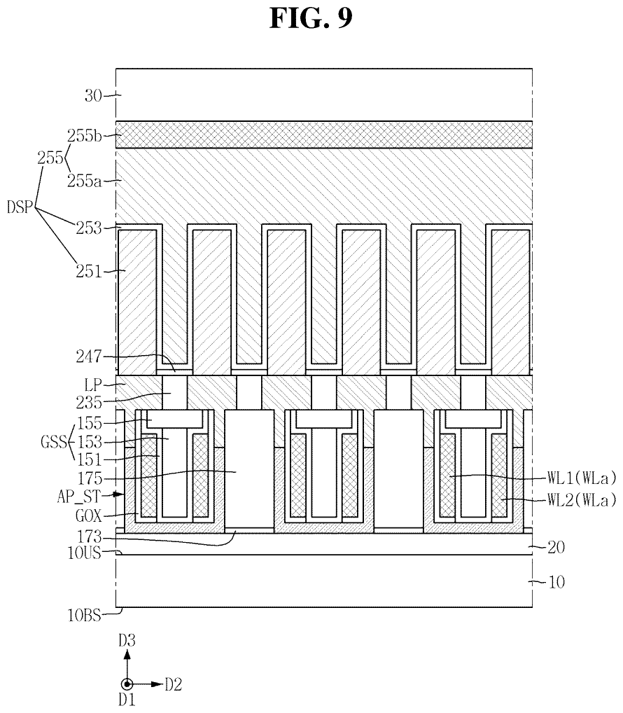

Next, referring to FIG. 9, the landing pad LP may be formed on the channel structure AP_ST and the protruding insulating pattern 175, the data storage pattern DSP may be formed on the landing pad LP, and a handling substrate 30 may be formed on the data storage pattern DSP.

A portion of the channel structure AP_ST may be removed such that a vertical level of the uppermost surface of the channel structure AP_ST may be lower than a vertical level of the upper surface of the protruding insulating pattern 175. Subsequently, a pre-landing pad film may be formed on the protruding insulating pattern 175, the gate isolation pattern GSS, and the channel structure AP_ST. The pre-landing pad film may be patterned such that the landing pads LP may be formed on the channel structure AP_ST.

Subsequently, the data storage pattern DSP may be formed on the landing pad LP. The data storage pattern DSP may be connected to the channel structure AP_ST and may be formed on the gate isolation pattern GSS.

Subsequently, the handling substrate 30 may be formed on the data storage pattern DSP.

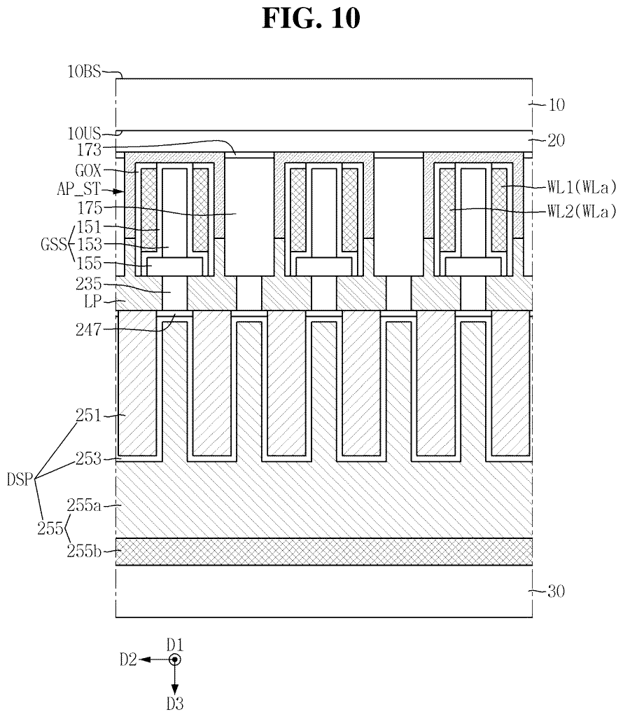

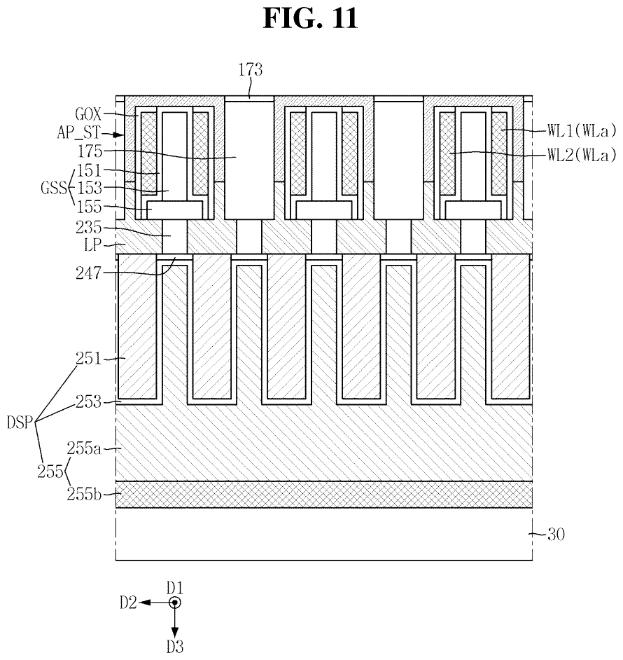

Next, referring to FIG. 10 and FIG. 11, the handling substrate 30 is turned upside down so that the lower surface 10BS of the auxiliary substrate 10 faces upwards, and the auxiliary substrate 10 and the first etch stop film 20 may be removed.

The resulting structure in FIG. 9 may be turned upside down so that the handling substrate 30 faces downward and the auxiliary substrate 10 faces upward. Subsequently, the auxiliary substrate 10 may be removed by performing a planarization process (CMP, Chemical Mechanical Polishing). The first etch stop film 20 may be removed in an etching process.

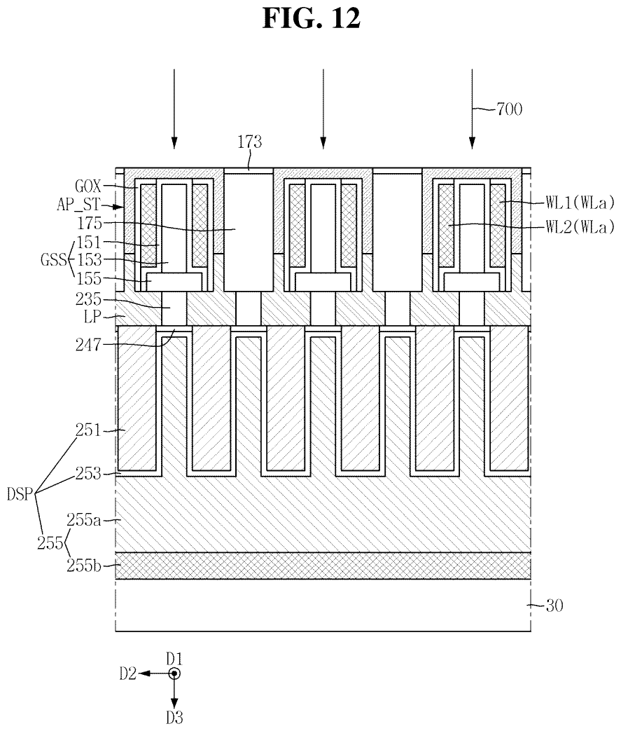

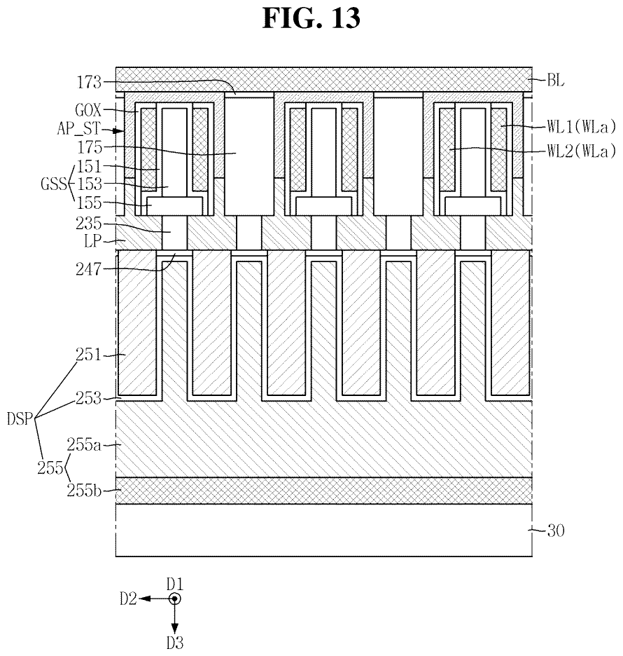

Next, referring to FIG. 12 and FIG. 13, plasma treatment 700 may be performed on the channel structure AP_ST, and then, the bit line BL may be formed on the channel structure AP_ST.

Before the bit line BL is formed, the plasma treatment 700 may be performed on the channel structure AP_ST. The plasma treatment may be performed by converting single gas or mixed gases of nitrogen (N₂), hydrogen (H₂), oxygen (O₂), fluorine (F), or argon (Ar) into plasma. When the plasma treatment 700 has been performed on the channel structure AP_ST, the electron concentration of the channel structure AP_ST increases and thus, the charge mobility may be improved. Therefore, the contact resistance between the channel structure AP_ST and the bit line BL may be lowered.

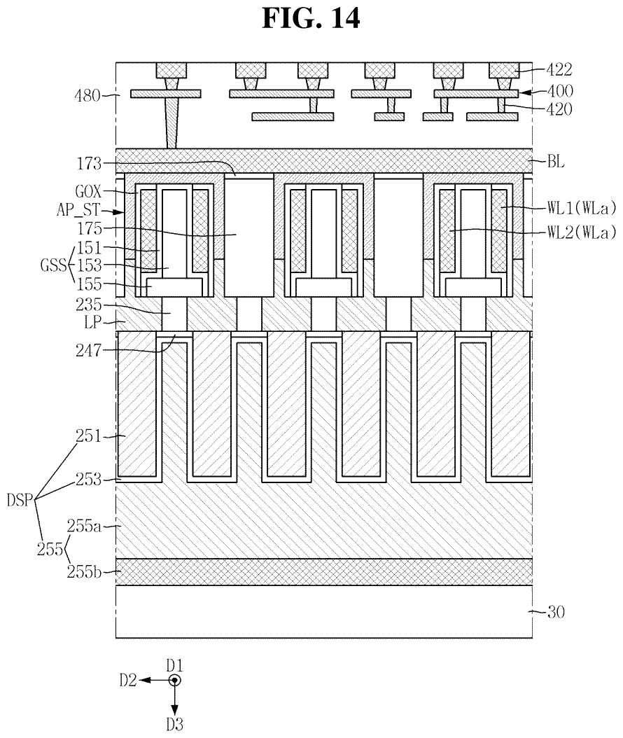

Next, referring to FIG. 14, the cell circuit wiring structure 400 and the upper bonding pad 422 may be formed on the bit line BL.

The cell circuit wiring structure 400 and the upper bonding pad 422 may be formed within the first cell interlayer insulating film 480. The first cell interlayer insulating film 480 may be formed on the bit line BL. The cell circuit wiring structure 400 may be electrically connected to the bit line BL. The upper bonding pad 422 may be formed on the cell circuit wiring structure 400.

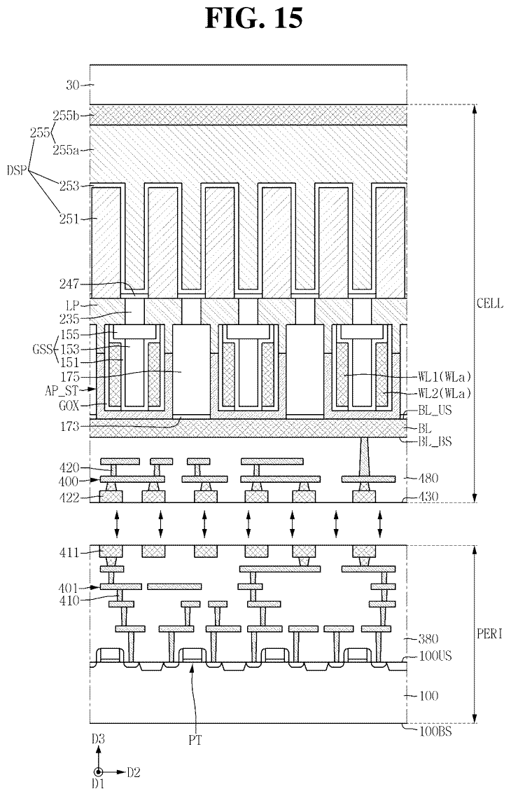

Next, referring to FIG. 15, the cell structure CELL and the peripheral circuit structure PERI may be coupled to each other.

The peripheral circuit structure PERI may include the peripheral circuit substrate 100, the peripheral circuit element PT formed on the peripheral circuit substrate 100, the peripheral circuit wiring structure 401 formed on the peripheral circuit element PT, and the lower bonding pad 411 formed on the peripheral circuit wiring structure 401.

The resulting structure in FIG. 14 may be turned upside down so that the handling substrate 30 faces upwardly and the upper bonding pad 422 faces downwardly. Subsequently, the upper bonding pad 422 may be bonded to the lower bonding pad 411 of the peripheral circuit structure PERI. The handling substrate 30 may then be removed.

Conventionally, the channel structure AP_ST including a metal oxide is formed on the bit line BL. When the channel structure AP_ST including the metal oxide has been formed on the bit line BL, the bit line BL is oxidized. Thus, selection of a type of the metal oxide is limited. Additionally, the bit line BL may be oxidized such that an interface resistance between the bit line BL and the channel structure AP_ST may rapidly increase.

However, in the semiconductor memory device according to some example embodiments of the present disclosure, the channel structure AP_ST including a metal oxide and the data storage pattern DSP may be first formed on the auxiliary substrate 10 and the first etch stop film 20. Then, the resulting structure may be turned upside down and then the bit line BL may be formed on the channel structure AP_ST. Rather than forming the bit line BL and then forming the channel structure AP_ST on the bit line BL, the channel structure AP_ST may be formed first, and then the bit line BL may be formed on the channel structure AP_ST. Thus, a contact resistance between the bit line BL and the channel structure AP_ST may be reduced in the above process sequence. Therefore, the metal oxide included in the channel structure AP_ST may include various phases of IGZO while not being affected or being less affected by temperature or oxygen partial pressure. Additionally, before forming the bit line BL, the plasma treatment may be performed on the channel structure AP_ST. As the plasma treatment has been performed, the electron concentration of the channel structure AP_ST may increase. After the plasma treatment has been performed on the channel structure AP_ST, the bit line BL may be formed thereon, such that the contact resistance between the channel structure AP_ST and the bit line BL may be lowered.

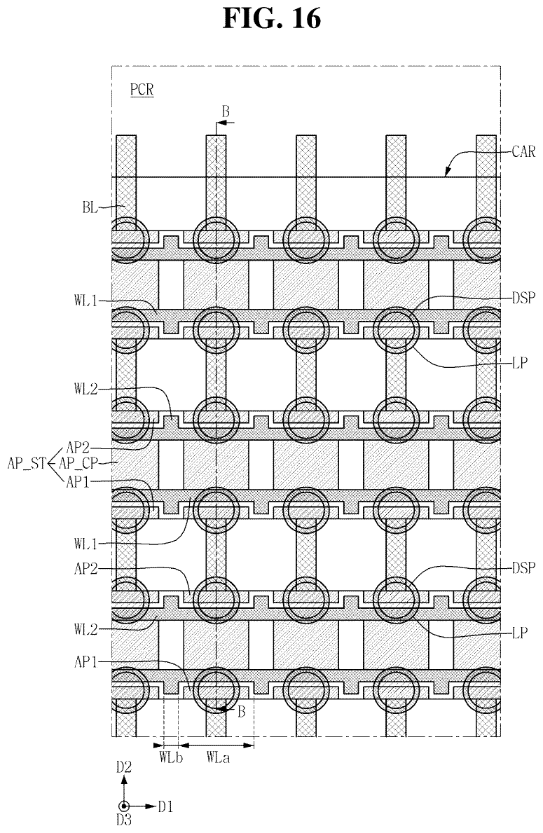

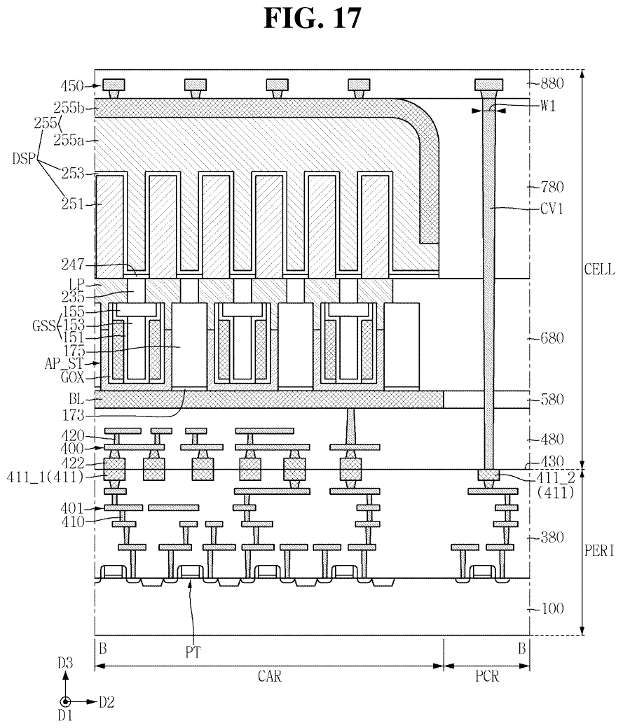

FIG. 16 and FIG. 17 are diagrams for illustrating a semiconductor memory device according to some example embodiments of the present disclosure. FIG. 17 is a cross-sectional view cut along line B-B in FIG. 16. For convenience of description, contents duplicate with what has been described above in FIGS. 1 to 4 are briefly described or descriptions thereof are omitted.

Referring to FIG. 16 and FIG. 17, the semiconductor memory device according to some example embodiments of the present disclosure may further include an upper wiring structure 450, a contact via CV1, and a lower bonding pad 411.

The upper wiring structure 450 may be disposed on the fifth cell interlayer insulating film 880. The upper wiring structure 450 may be disposed on the data storage pattern DSP. The upper wiring structure 450 may be electrically connected to the data storage pattern DSP. That is, the upper wiring structure 450 may be connected to a capacitor.

The lower bonding pad 411 may include a first lower bonding pad 411_1 and a second lower bonding pad 411_2. The first lower bonding pad 411_1 may be disposed in a cell array area CAR, and the second lower bonding pad 411_2 may be disposed in a peripheral circuit area PCR. However, the present disclosure is not limited thereto. The second lower bonding pad 411_2 may be spaced apart from the first lower bonding pad 411_1 in the first direction D1 or the second direction D2.

The first lower bonding pad 411_1 may be connected to the upper bonding pad 422, while the second lower bonding pad 411_2 may not be connected to the upper bonding pad 422. That is, the second lower bonding pad 411_2 may not be in contact, for example direct contact, with the upper bonding pad 422.

The contact via CV1 may be disposed on the peripheral circuit area PCR and outside the cell array area CAR. The contact via CV1 may be disposed to be spaced apart from the bit line BL in the second direction D2. The contact via CV1 may extend through the first to fourth cell interlayer insulating films 480, 580, 680, and 780.

The contact via CV1 may be connected to the upper wiring structure 450 and the second lower bonding pad 411_2. The second lower bonding pad 411_2 may be connected, for example directly connected, to the contact via CV1. A first width W1 of the contact via CV1 may become smaller as it extends away from the upper wiring structure 450 in the third direction D3. That is, the first width W1 of the contact via CV1 may become smaller as it extends from the upper wiring structure 450 toward the second lower bonding pad 411_2.

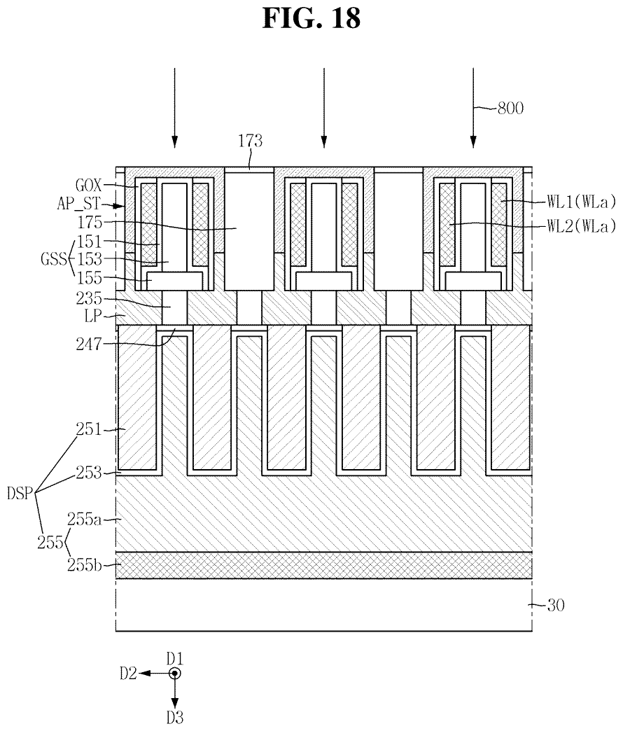

FIG. 18 is a diagram for illustrating a semiconductor memory device manufacturing method according to some example embodiments of the present disclosure. For convenience of description, contents duplicate with what have been described above in FIGS. 5 to 15 are briefly described or descriptions thereof are omitted.

FIG. 18 is a diagram for illustrating a process before the auxiliary substrate 10 and the first etch stop film 20 are removed and the bit line BL is formed on the channel structure AP_ST in FIGS. 11 to 13.

Referring to FIG. 18, an ion implantation process 800 may be performed on the channel structure AP_ST. Impurities may be contained in the channel structure AP_ST via the ion implantation process 800. The impurities may include at least one of phosphorus (P), arsenic (As), antimony (Sb), bismuth (Bi), and/or boron (B). However, example embodiments of the present disclosure are not limited thereto.

When the impurities are contained in the channel structure AP_ST via the ion implantation process 800, the concentration of electrons contained in the channel structure AP_ST may increase. Therefore, the contact resistance between the bit line BL and the channel structure AP_ST may be lowered. Descriptions about a subsequent process may be substantially the same as the descriptions as set forth above with reference to FIGS. 13 to 15.

Although example embodiments of the present disclosure have been described with reference to the accompanying drawings, the present disclosure is not limited to the above example embodiments, but may be implemented in various different forms. A person skilled in the art may appreciate that the present disclosure may be practiced in other concrete forms without changing the technical spirit or essential characteristics of the present disclosure. Therefore, it should be appreciated that the example embodiments as described above are not restrictive but illustrative in all respects.

What is claimed is:

1. A semiconductor memory device comprising:
a peripheral circuit substrate;
a peripheral circuit element on the peripheral circuit substrate;
a peripheral circuit wiring structure on the peripheral circuit substrate and connected to the peripheral circuit element;
a lower bonding pad on the peripheral circuit wiring structure;
a bit line on the lower bonding pad and including an upper surface and a bottom surface opposite to each other in a first direction, wherein the bit line extends in a second direction, and the bottom surface of the bit line faces the peripheral circuit substrate;
a first channel pattern on the upper surface of the bit line and including a metal oxide;
a second channel pattern on the upper surface of the bit line and including the metal oxide, wherein the first channel pattern is spaced apart from the first channel pattern in the second direction;
a first word line between the first channel pattern and the second channel pattern and extending in a third direction;
a second word line disposed between the first channel pattern and the second channel pattern and extending in the third direction, wherein the second word line is spaced apart from the first word line in the second direction;
a first capacitor and a second capacitor respectively on the first channel pattern and the second channel pattern, and each of the first capacitor and the second capacitor respectively connected to the first channel pattern and the second channel pattern;
a cell circuit wiring structure on the bottom surface of the bit line and connected to the bit line; and
an upper bonding pad between the cell circuit wiring structure and the lower bonding pad, wherein the upper bonding pad is in contact with the lower bonding pad.

2. The semiconductor memory device of claim 1, further comprising:
an upper wiring structure on the upper surface of the bit line and connected to the first capacitor and the second capacitor.

3. The semiconductor memory device of claim 2, further comprising:
a contact via spaced apart from the bit line in the second direction, extending in the first direction, and connected to the upper wiring structure,
wherein the lower bonding pad includes a first lower bonding pad and a second lower bonding pad,
wherein the first lower bonding pad is in contact with the upper bonding pad,
wherein the second lower bonding pad is connected to the contact via.

4. The semiconductor memory device of claim 3, wherein the second lower bonding pad is not in contact with the upper bonding pad.

5. The semiconductor memory device of claim 3, wherein a first width of the contact via becomes smaller as the contact via extends away from the upper wiring structure in the first direction.

6. The semiconductor memory device of claim 1, further comprising:
a gate isolation pattern isolating the first word line and the second word line from each other; and
a connection channel pattern on the bit line and connecting the first channel pattern and the second channel pattern to each other,
wherein the gate isolation pattern is on the connection channel pattern.

7. The semiconductor memory device of claim 6, wherein the first channel pattern, the second channel pattern, and the connection channel pattern include a plasma-treated surface.

8. The semiconductor memory device of claim 6, wherein the first channel pattern, the second channel pattern, and the connection channel pattern are doped with impurities.

9. The semiconductor memory device of claim 1, further comprising:
a first landing pad on the first channel pattern connecting the first channel pattern and the first capacitor to each other, a second landing pad on the second channel pattern connecting the second channel pattern and the second capacitor to each other,
wherein each of the first capacitor and the second capacitor includes a storage electrode on each of the landing pads, a capacitor dielectric film on the storage electrode, and a plate electrode on the capacitor dielectric film.

10. The semiconductor memory device of claim 1, wherein
the peripheral circuit wiring structure includes a plurality of first vias,
the cell circuit wiring structure includes a plurality of second vias,
a width of the first vias becomes smaller as the first vias extends away from the lower bonding pad in the first direction, and
a width of the second vias becomes smaller as the second vias extends away from the upper bonding pad.

11. A semiconductor memory device comprising:
a peripheral circuit substrate;
a peripheral circuit element on the peripheral circuit substrate;
a peripheral circuit wiring structure on the peripheral circuit substrate and connected to the peripheral circuit element;
a bit line on the peripheral circuit wiring structure and including an upper surface and a bottom surface opposite to each other in a first direction, wherein the bit line extends in a second direction and the bottom surface of the bit line faces the peripheral circuit substrate;
a first channel pattern on the upper surface of the bit line;
a second channel pattern on the upper surface of the bit line and spaced apart from the first channel pattern in the second direction;
a first word line between the first channel pattern and the second channel pattern and extending in a third direction;
a second word line between the first channel pattern and the second channel pattern, extending in the third direction, and spaced apart from the first word line in the second direction;
a first capacitor and a second capacitor respectively on the first channel pattern and the second channel pattern, and each of the first capacitor and the second capacitor respectively connected to the first channel pattern and the second channel pattern;
an upper bonding pad on the bottom surface of the bit line and connected to the bit line;
a first lower bonding pad between the upper bonding pad and the peripheral circuit wiring structure and connected to the peripheral circuit wiring structure, wherein the first lower bonding pad is in contact with the upper bonding pad; and
a second lower bonding pad spaced apart from the first lower bonding pad in the second direction, and connected to the peripheral circuit wiring structure, wherein the second lower bonding pad is not in contact with the upper bonding pad.

12. The semiconductor memory device of claim 11, further comprising:
an upper wiring structure on the upper surface of the bit line and connected to the first capacitor and the second capacitor.

13. The semiconductor memory device of claim 12, further comprising:
a contact via spaced apart from the bit line in the second direction, extending in the first direction, and connected to the upper wiring structure,
wherein the second lower bonding pad is connected to the contact via.

14. The semiconductor memory device of claim 13, wherein a first width of the contact via becomes smaller as the contact via extends away from the upper wiring structure in the first direction.

15. The semiconductor memory device of claim 11, wherein the first channel pattern and the second channel pattern are treated with plasma.

16. The semiconductor memory device of claim 11, wherein the first channel pattern and the second channel pattern are doped with impurities.

17. A semiconductor memory device comprising:
a peripheral circuit substrate;
a peripheral circuit element on the peripheral circuit substrate;
a peripheral circuit wiring structure on the peripheral circuit substrate and connected to the peripheral circuit element;
a first lower bonding pad and a second lower bonding pad on the peripheral circuit wiring structure;
a bit line on the first and second lower bonding pads, the bit line including an upper surface and a bottom surface opposite to each other in a first direction, wherein the bit line extends in a second direction, and the bottom surface of the bit line faces the peripheral circuit substrate;
a first channel pattern on the upper surface of the bit line and including a metal oxide;
a second channel pattern disposed on the upper surface of the bit line and including the metal oxide, wherein the second channel pattern is spaced apart from the first channel pattern in the second direction;
a first word line between the first channel pattern and the second channel pattern and extending in a third direction;
a second word line between the first channel pattern and the second channel pattern, extending in the third direction, and spaced apart from the first word line in the second direction;
a first capacitor and a second capacitor respectively on the first channel pattern and the second channel pattern, and each of the first capacitor and the second capacitor respectively connected to the first channel pattern and the second channel pattern;
a cell circuit wiring structure on the bottom surface of the bit line and connected to the bit line;
an upper bonding pad between the cell circuit wiring structure and the first lower bonding pad, wherein the upper bonding pad is in contact with the first lower bonding pad;
an upper wiring structure connected to the first capacitor and the second capacitor; and
a contact via spaced apart from the bit line in the second direction and connecting the upper wiring structure and the second lower bonding pad to each other,
wherein the upper bonding pad is not in contact with the second lower bonding pad.

18. The semiconductor memory device of claim 17, wherein a first width of the contact via becomes smaller as the contact via extends in a direction from the upper wiring structure to the second lower bonding pad.

19. The semiconductor memory device of claim 17, further comprising:
a gate isolation pattern isolating the first word line and the second word line from each other; and
a connection channel pattern on the bit line and connecting the first channel pattern and the second channel pattern to each other,
wherein the gate isolation pattern is on the connection channel pattern.

20. The semiconductor memory device of claim 17, wherein
the peripheral circuit wiring structure includes a plurality of first vias,
the cell circuit wiring structure includes a plurality of second vias,
a width of the first vias becomes smaller as the first vias extends away from the first lower bonding pad in the first direction, and
a width of the second vias becomes smaller as the second vias extends away from the upper bonding pad.
